(19) United States
(12) Patent Application Publication
(10) Pub. No.: US 2010/0165727 A1
(43) Pub. Date: Jul. 1, 2010

(54) PHASE CHANGE MATERIAL MEMORY HAVING NO ERASE CYCLE

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/650,682

(22) Filed: Dec. 31, 2009

Related U.S. Application Data
(60) Provisional application No. 61/204,014, filed on Dec. 31, 2008.

(51) Int. Cl. G11C 11/00; G11C 7/00

(52) U.S. Cl. 365/163; 365/218; 365/189.16; 365/148

(57) ABSTRACT

An information storage array includes a programmable material at one or more storage locations and pulse generation circuitry for generating at least two pulses—in particular, a write pulse that writes a value into the programmable material an erase pulse that erases a value from the programmable material. In general, the erase pulse is greater in duration than the write pulse. Either the write pulse or the erase pulse is selected based at least in part on a state of a data bit to be stored in the programmable material.

### CROSS-REFERENCE TO RELATED APPLICATIONS

This application claims priority to and the benefit of, and incorporates herein by reference in its entirety, U.S. Provisional Patent Application No. 61/204,014, which was filed on Dec. 31, 2008.

### TECHNICAL FIELD

In various embodiments, the present invention relates to the design and operation of solid state memory arrays, and more particularly to the design and operation of memory arrays incorporating phase-change or resistive-change materials.

### BRIEF DESCRIPTION OF THE DRAWINGS

FIG. 1 is a schematic representation of a circuit for writing and erasing a memory element;

FIG. 2 is a schematic representation of a circuit for writing and erasing a memory element in accordance with an embodiment of the present invention; and

FIG. 3 is a flowchart illustrating a method for changing the state of a programmable material at a storage location in accordance with an embodiment of the present invention.

### BACKGROUND

Many types of non-volatile memory-storage cells exist in the prior art, including trapped-charge devices (e.g., flash memory) and altered-resistivity devices such as phase-change random-access memory (PRAM), resistive random-access memory (RRAM), or chalcogenide-based memories. Flash memory is relatively fast but suffers from short data-retention times. While phase-change materials generally retain data for longer times and have access times comparable to those of flash memories, process integration of phase-change materials may challenging due to their inability to withstand elevated thermal budgets.

Different forms of RRAM utilize different dielectric materials, spanning from perovskites to transition metal oxides to chalcogenides. An RRAM device typically features a conduction path (e.g., a filament or other path formed by application of a high voltage) through a dielectric, which is normally insulating. The conduction path may be broken (resulting in high resistance) and re-formed (resulting in low resistance) by appropriately applied voltages. By incorporating a resistive-change material in the memory cell, one alters the resistivity of the current path through the storage cell, thereby changing the state of the stored bit or bits. For examples of such resistive-change materials, see, e.g., U.S. Pat. Nos. 6,531,371, 6,867,996, 6,870,755, 6,946,702, 7,067,865, 7,157,750, and 7,292,469, the entire disclosure of each of which is incorporated by reference.

PRAM devices incorporate phase-change materials (PCMs) such as alloys of germanium, antimony, and tellurium (GST or, typically, Ge₂Sb₂Te₅). Exemplary devices incorporating GST are disclosed in, e.g., U.S. Pat. Nos. 3,983,542, 4,646,266, and 5,414,271, the entire disclosure of each of which is incorporated by reference. GST may be placed into its crystalline phase via application of a current through the cell sufficient to heat the GST followed by a slow diminishment of the current and associated heat. The slow cooling of the GST permits the atoms of the GST to align themselves into a crystalline phase. In order to place the GST into its amorphous state, the current is cut off abruptly. The resulting rapid cooling traps the GST atoms into the amorphous phase because they lack sufficient time to rearrange properly. Intermediate phases may be achieved by current reduction and associated cooling at rates between the two above-described points.

Many types of non-volatile storage cells exist in the prior art, including trapped charge devices (such as flash memory), altered resistivity devices (such as PRAM (e.g., phase change or chalcogenide memory) and RRAM), and many more. In general, non-volatile storage cells are programmed in a a write cycle and an erase cycle. Because the write cycle is generally faster than the erase cycle, memory devices utilizing phase change and resistive change materials have separate erase and write cycles; this separation requires that the cells first be erased and then written at a later time. Clearly, there is a need for a memory device capable of performing both erase and write at the same time.

### SUMMARY OF THE INVENTION

The present invention relates to an electronic memory device that utilizes resistive change elements for storage. Embodiments of the invention are capable of being programmed without first being erased and, moreover, may be both erased and written at the same time.

In general, in a first aspect, embodiments of the invention include an information storage device that includes a programmable material at a storage location and pulse-generation circuitry. The pulse-generation circuitry generates (i) a write pulse that writes a value into the programmable material and (ii) an erase pulse that erases a value from the programmable material. The erase pulse is greater in duration than the write pulse. A selector selects the write pulse and/or the erase pulse based at least in part on a state of a data bit to be stored in the programmable material.

The programmable material may include a phase change material, dielectric material, a perovskite, and/or a transition metal oxide. The phase change material may include a chalcogenide alloy, germanium, antimony, and/or telluride. The pulse-generation circuitry may further generate additional, selectable pulse durations between a shortest pulse and a longest pulse.

In general, in another aspect, embodiments of the invention include a method for changing the state of a programmable material at a storage location. The method begins with generating a first pulse for writing a value into a programmable material. A a second pulse (greater in duration than the first pulse) is generated for erasing a value from the programmable material. One of the first pulse or the second pulse is selected based at least in part on a state of a data bit to be stored in the programmable material. A state of the programmable material is changed with the selected pulse.

The first pulse may be approximately 10 ns long and the second pulse may be approximately 500 ns long. The states of a plurality of programmable materials may be changed, and at least two programmable materials may be in different sub-arrays. The programmable material may be erased by writing a 0.

In general, in another aspect, embodiments of the invention include an information storage device that includes one or more storage arrays. A storage array includes a programmable material at a storage location and pulse generation circuitry for generating (i) a write pulse that writes a value into the programmable material and (ii) an erase pulse that erases a value from the programmable material The erase pulse is greater in duration than the write pulse. A selector selects one of the write pulse and erase pulse based at least in part on a state of a data bit to be stored in the programmable material. The information storage device may be a compact flash memory, secure digital memory, multimedia card, PCMCIA card, and/or memory stick.

### DESCRIPTION OF THE PREFERRED EMBODIMENT

Embodiments of the present invention address the need for an electronic memory device capable of being programmed without first being erased and in addition, which may be both erased and written at the same time. While specific time intervals and other related parameters are described herein in exemplary embodiments, the approach of the present invention may be utilized more broadly in a wide range of non-volatile memory devices. For example, while PCM materials are described herein, the approach of the present invention may be applied to materials other than PCM.

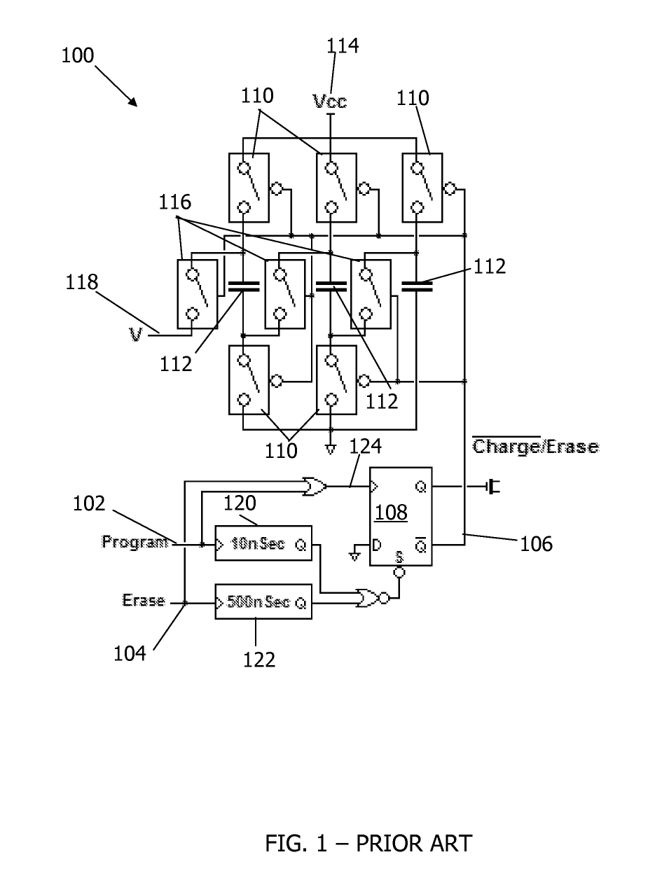

FIG. 1 is a schematic diagram that illustrates prior-art timing circuitry 100 for separate program 102 and erase 104 inputs. When neither the program 102 nor the erase 104 input is asserted, the output 106 of the storage element 108 is de-asserted, causing the switches 110 to charge the capacitors 112 to the supply voltage 114. When either the program 102 or the erase 104 input is asserted (e.g., raised high), the output 106 of the storage element 108 is asserted, thereby changing the state of the switches 110, 116 such that the switches 116 assert a voltage on the output node 118. The storage element 108 may be any appropriate storage device, such as an edge-triggered or level-sensitive latch or flip-flop. Depending on the polarity of the switches 110, 116, the output 106 of the storage element 108 may be a non-inverting Q output or an inverting Q̅ output.

Two delay lines, a first delay line 120 and a second delay line 122, may be connected to the program 102 and erase 104 inputs, respectively. In one embodiment, the amount of delay introduced by the first delay line 120 is approximately 10 ns and the amount of delay introduced by the second delay line 122 is 500 ns. The outputs of the delay lines 120, 122 may be ORed together to generate a storage device input signal 124. This signal 124 may be a pulse that will cause the output 106 of the storage element 108 to de-assert (e.g., go low) at an appropriate time. For example, asserting the program input 102 may immediately cause the charge/erase output 106 of the storage element 108 to assert, and the delay line 120 will cause the output 106 to de-assert 10 ns later, which may be an appropriate amount of time to program a value into a storage cell. Similarly, asserting the erase input 104 may also cause the charge/erase output 106 to assert, and the delay line 122 will cause the output 106 to de-assert 500 ns later, a length of time that may be appropriate to erase a storage element. Embodiments of the present invention are not limited to any particular time for each delay line 120, 122, however, and any necessary time may be assigned to either delay line. Furthermore, embodiments of the present invention are not limited to the capacitor 112 and switch 110, 116 charging scheme shown in FIG. 1, and the scope of the current invention extends to any control circuitry for providing a state-changing voltage or current to a memory element that may be controlled by similar program and erase signals.

An additional transistor 126 is shown that may be optionally used to discharge any portion of the circuit 100 as desired to increase the rate of circuit quenching. For example, the transistor 126 may be used to connect the output node 118 to ground to discharge any charge in the array circuitry connected to that circuit point.

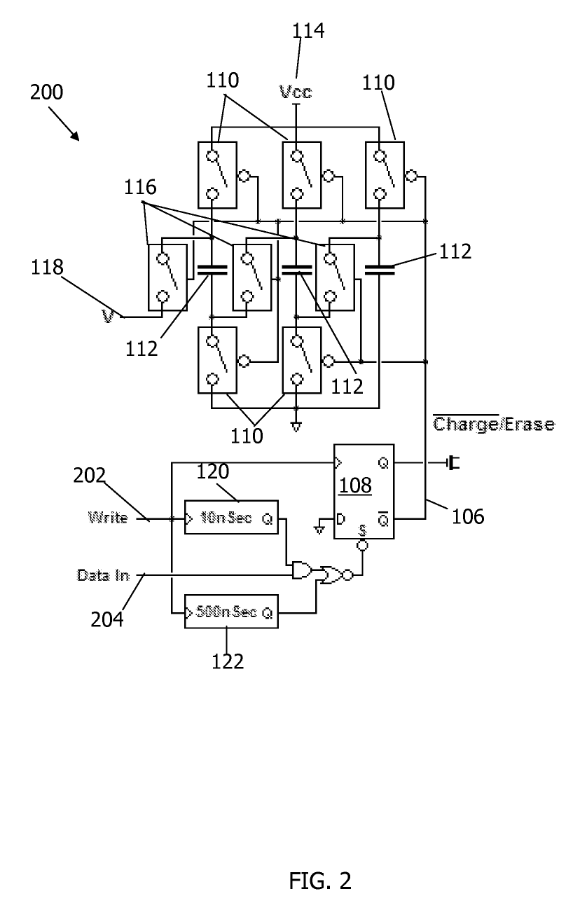

FIG. 2 illustrates a circuit 200 that, in accordance with an embodiment of the present invention, includes a write input 202 and a data bit input 204 instead of program and erase inputs as described in the above circuit. In one embodiment, the write input 202 enables the array to be written with the value represented by the data bit input 204. In this embodiment, the programming current is quenched after approximately 500 ns if the data bit 204 is de-asserted (e.g., low). The data bit 204 is ANDed with the 10 ns delay line 120 output, thereby blocking that signal from setting the storage element 108. When the data bit 204 is high, however, the 10 ns delayed pulse passes through, causing the current to be quenched after only 10 ns. With this circuit 200 assigned to each memory array or sub-array, 1 bits and 0 bits may be written simultaneously to multiple arrays in the memory device (i.e., a single bit to each array). No additional circuitry may be required to implement the functions for program, erase and write, because erase may be implemented by writing a 0 to all memory bits. A ready/busy output may optionally be incorporated as will be apparent to one skilled in the art.

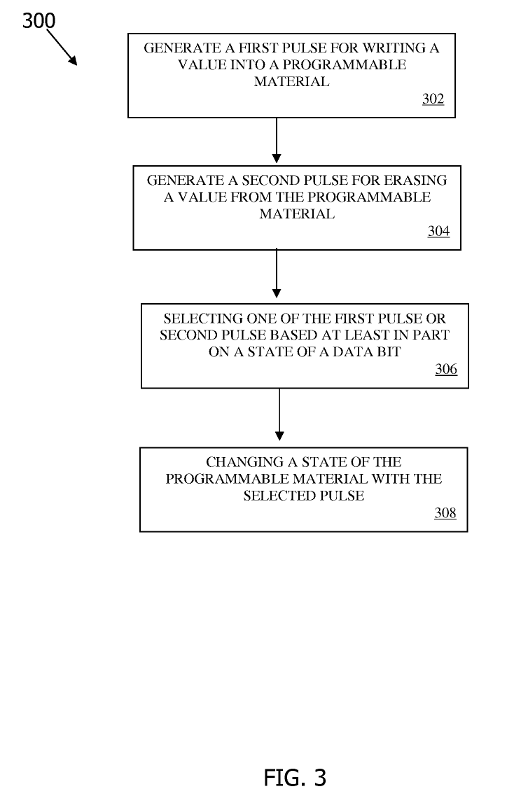

FIG. 3 is a flowchart illustrating, in one embodiment, a method 300 for changing the state of a programmable material at a storage location. A first pulse is generated for writing a value into a programmable material (Step 302), and a second pulse is generated for erasing a value from the programmable material (Step 304). The second pulse is greater in duration than the first pulse. Either the first pulse or the second pulse is selected based at least in part on a state of a data bit to be stored in the programmable material (Step 306). A state of the programmable material is changed using the selected pulse (Step 308).

In one embodiment, two or more sets of capacitors 112 are incorporated into the memory array such that, while one set is switched in series onto the array to erase (i.e., in a discharge mode), another set is switched across the positive supply voltage (in, e.g., a charging mode). This simultaneous charging and discharging of different sets of capacitors 112 may enable one set of capacitors 112 to always be charged and ready to erase the next bit in the array. Many other variations are possible, however, for the current shaping and voltage generation other than the switched capacitor approach depicted herein. For example, a 1 bit and a 0 bit may be differently defined within the teaching of the present invention. For a multiple-bit-per-cell implementation, two or more data bits may be decoded (by, for example, by a one-of-many selector) wherein each selector output corresponds to enabling and passing a different delay line output to the storage element 108 for quenching and therein setting the programmable material to intermediate resistance values. In addition, the present invention may be used with materials other than PCM.

Writing the storage cell in a memory array is accomplished by heating the GST in the cell. This heating may be performed by passing a current through the cell or by passing a current near enough to the cell to heat it. A bulk erase may be performed by heating the array or a portion of the array, thereby erasing multiple bits concurrently. Heating successive areas of the array may enable lower peak power consumption by starting the erase of groups of bits in succession (overlapping the heating of some bits while not necessarily starting and stopping the heating simultaneously, although this too could be done). Heating the memory device in a heating chamber may erase the entire array at once. The storage cell may be connected at a point of overlap of a row line or a bit line and a column line or a word line of a memory array such as a diode matrix memory array (with the anode to the row or bit line and the cathode to the column or word line or vice versa).

The present invention may find applicability in memory devices comprising an array of multiple sub-arrays, one or more of which may be accessed simultaneously. More bits of information may be read or written simultaneously to increase throughput or fewer bits of information may be read or written simultaneously to conserving power. Each sub-component/sub-array to be written or erased may have its own capacitor set 100 according to embodiments of the present invention. In one embodiment, a single capacitor set 100 is shared by more than one sub-component. Embodiments of the present invention may be used in memory devices comprising an array of multiple sub-arrays wherein the memory device is tiled into many sub-arrays for other purposes. Each sub-array may have its own quench control circuit corresponding to the data bit to be written to that location in that sub-array. Furthermore, the data bits may be provided from a latching circuit that retains the data bits such that the data bits may be removed from the data bus to the device during programming.

Embodiments of the present invention may be utilized in memory devices used in systems for storing digital text, digital books, digital music, digital audio, digital photography (wherein one or more digital still images is stored, including sequences of digital images), digital video, digital cartography (wherein one or more digital maps is stored), and any other digital or digitized information as well as any combinations thereof. These memory devices may be embedded, removable, or removable and interchangeable among other devices that access the data therein. They may be packaged in any variety of industry-standard form factors such as compact flash, secure digital, multimedia cards, PCMCIA cards, memory stick, and/or any of a large variety of integrated circuit packages including ball grid arrays, dual in-line packages (DIPs), SOICs, PLCCs, TQFPs, and the like, as well as in proprietary form factors and custom-designed packages. These packages may contain a single memory chip, multiple memory chips, or one or more memory chips along with other logic devices or other storage devices such as PLDs, PLAs, micro-controllers, microprocessors, memory controller chips or chip-sets, or other custom or standard circuitry. Packaging may include a connector for making electrical contact with another device when the device is removable or removable and interchangeable.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An information storage device comprising:
a programmable material at a storage location;
pulse-generation circuitry for generating (i) a write pulse that writes a value into the programmable material and (ii) an erase pulse that erases a value from the programmable material, the erase pulse being greater in duration than the write pulse; and
a selector for selecting one of the write pulse and erase pulse based at least in part on a state of a data bit to be stored in the programmable material.

2. The storage array of claim 1, wherein the programmable material comprises at least one of a phase change material, dielectric material, a perovskite, or a transition metal oxide.

3. The storage array of claim 1, wherein the phase change material comprises at least one of a chalcogenide alloy, germanium, antimony, or telluride.

4. The storage array of claim 1, wherein the pulse-generation circuitry further generates additional, selectable pulse durations between a shortest pulse and a longest pulse.

5. A method for changing the state of a programmable material at a storage location, the method comprising:
generating a first pulse for writing a value into a programmable material;
generating a second pulse for erasing a value from the programmable material, the second pulse being greater in duration than the first pulse;
selecting one of the first pulse or the second pulse based at least in part on a state of a data bit to be stored in the programmable material; and
changing a state of the programmable material with the selected pulse.

6. The method of claim 5, wherein the first pulse is approximately 10 ns long.

7. The method of claim 5, wherein the second pulse is approximately 500 ns long.

8. The method of claim 5, further comprising changing the states of a plurality of programmable materials.

9. The method of claim 8, wherein at least two programmable materials are in different sub-arrays.

10. The method of claim 8, further comprising erasing the programmable material by writing a 0.

11. An information storage device comprising one or more storage arrays, wherein at least one storage array comprises:
a programmable material at a storage location;
pulse generation circuitry for generating (i) a write pulse that writes a value into the programmable material and (ii) an erase pulse that erases a value from the programmable material, the erase pulse being greater in duration than the write pulse; and
a selector for selecting one of the write pulse and erase pulse based at least in part on a state of a data bit to be stored in the programmable material.

12. The information storage device of claim 11, wherein the information storage device is one of a compact flash memory, secure digital memory, multimedia card, PCMCIA card, or memory stick.
